(19) United States
(12) Patent Application Publication
(10) Pub. No.: US 2008/0082872 A1
(43) Pub. Date: Apr. 3, 2008

(54) Memory controller, memory system, and data transfer method

(75) Inventor: Toshiro Nagasaka, Ome-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/902,855

(22) Filed: Sep. 26, 2007

(30) Foreign Application Priority Data
Sep. 29, 2006 (JP) 2006-268258

(51) Int. Cl. G11C 29/00

(52) U.S. Cl. 714/719; 714/E11.178

(57) ABSTRACT

According to one embodiment, a memory controller comprises a reading section which reads data from a data part of a nonvolatile memory including the data part for storing data and an extended part for storing an ECC for the data and provides the read data, a computing section which calculates an ECC on the basis of the read data in parallel with the reading of data at the reading section and holds the result of the calculation, a comparing section which reads the ECC stored in the extended part of the nonvolatile memory and compares the read ECC with the result of the calculation at the computing section, and a section which outputs an ECC error interruption signal when the comparison at the comparing section has shown an disagreement.

### CROSS-REFERENCE TO RELATED APPLICATIONS

This application is based upon and claims the benefit of priority from Japanese Patent Application No. 2006-268258, filed Sep. 29, 2006, the entire contents of which are incorporated herein by reference.

### BACKGROUND

1. Field

One embodiment of the present invention relates to ECC-added data communication techniques, and more particularly to the technique for transferring data between semiconductor memories.

2. Description of the Related Art

In recent years, a low-price large-capacity nonvolatile memory, such as a NAND flash memory, has begun to be used widely. A method of expanding the necessary part of the data stored in a nonvolatile memory into a high-speed accessible general-purpose volatile memory has been in wide use.

However, as the nonvolatile memory has a larger capacity, the chances get higher that communication errors will occur. For this reason, it is common practice to add an error correction code (ECC) to data, store the resulting data into a nonvolatile memory, and then check whether an error has occurred in transferring the data to a volatile memory (refer to Jpn. Pat. Appln. KOKAI Publication No. 2004-126911).

At the time of data transfer between memories as described above or of general communication of ECC-added data, if it takes time to check for data errors on the basis of an ECC, the comprehensive data transfer time gets that much longer.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram showing the basic configuration of a memory system according to an embodiment of the invention;

FIG. 2A and FIG. 2B show the configuration and function of a nonvolatile memory 107; and

FIG. 3 is a flowchart to help explain the operation of the memory system according to the embodiment.

### DETAILED DESCRIPTION

Various embodiments according to the invention will be described hereinafter with reference to the accompanying drawings. In general, according to one embodiment of the invention, there is provided a memory controller comprising: a reading section which reads data in the data part from a nonvolatile memory including a data part for storing data and an extended part for storing an ECC for the data and provides the read data; a computing section which calculates an ECC on the basis of the read data in parallel with the reading of data at the reading section and holds the result of the calculation; a comparing section which reads the ECC stored in the extended part of the nonvolatile memory and compares the read ECC with the result of the calculation at the computing section; and a section which outputs an ECC error interruption signal when the comparison at the comparing section has shown an disagreement.

With the above configuration, it is possible to shorten the transfer time of ECC-added data and realize high-speed high-reliability data transfer.

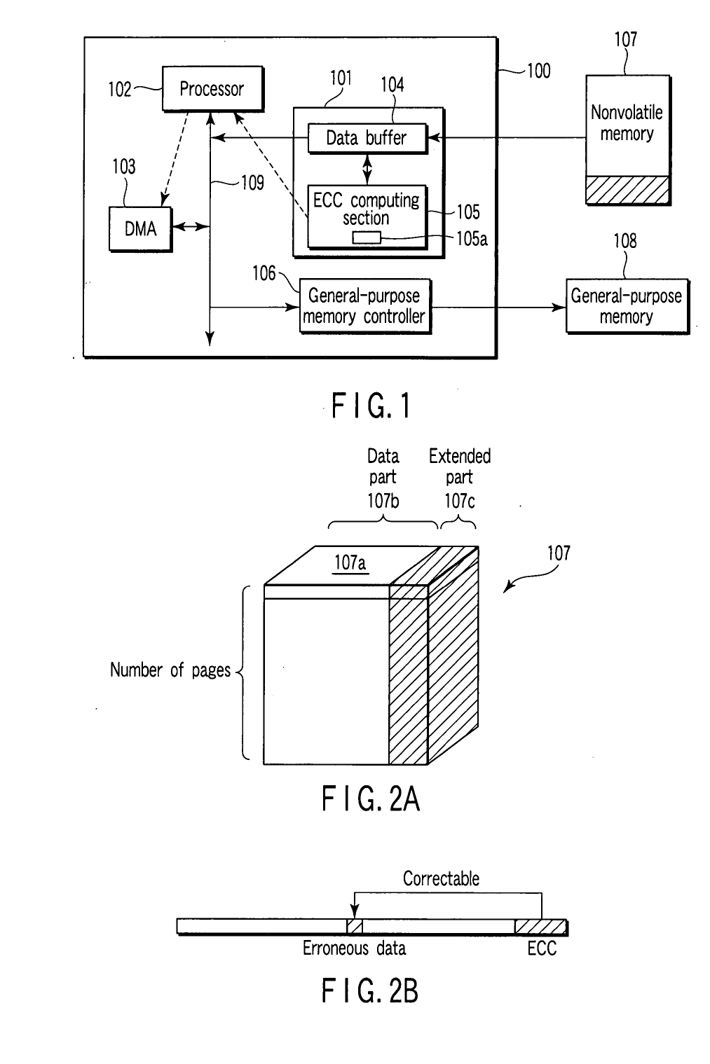

FIG. 1 is a block diagram showing the basic configuration of a memory system according to an embodiment of the invention.

A semiconductor integrated circuit 100, which is composed of one chip, includes a nonvolatile memory controller 101, a processor 102, a DMA controller 103, and a general-purpose memory controller 106. The nonvolatile memory controller 101, processor 102, DMA controller 103, and general-purpose memory controller 106 are connected to one another via a data bus 9.

The nonvolatile memory controller 101 includes a data buffer 104 and an ECC computing circuit 105. A nonvolatile memory 107, such as a NAND flash memory, provided outside the semiconductor integrated circuit 100 is connected to the data buffer 104. A general-purpose volatile memory 108, such as DRAM, provided outside the semiconductor integrated circuit 100 is connected to the general-purpose memory controller 106.

FIG. 2A shows a configuration of the nonvolatile memory 107. The nonvolatile memory 107 is composed of a stack of a plurality of pages. A page 107a is composed of a data part 107b which stores data and an extended part 107c in which an ECC has been stored. The page 107a has a data capacity of, for example, 528 bytes, of which 512 bytes are allocated to the data part 107b and 16 bytes are allocated to the extended part 107c.

Generally, an ECC means a code added to the target data or an encoding method to detect data errors occurred due to noise in the communication circuit and/or signal attenuation and correct the errors when data is transferred via the communication circuit. An ECC enables errors in the data to be corrected as in FIG. 2B similarly to a general method, such as parity error.

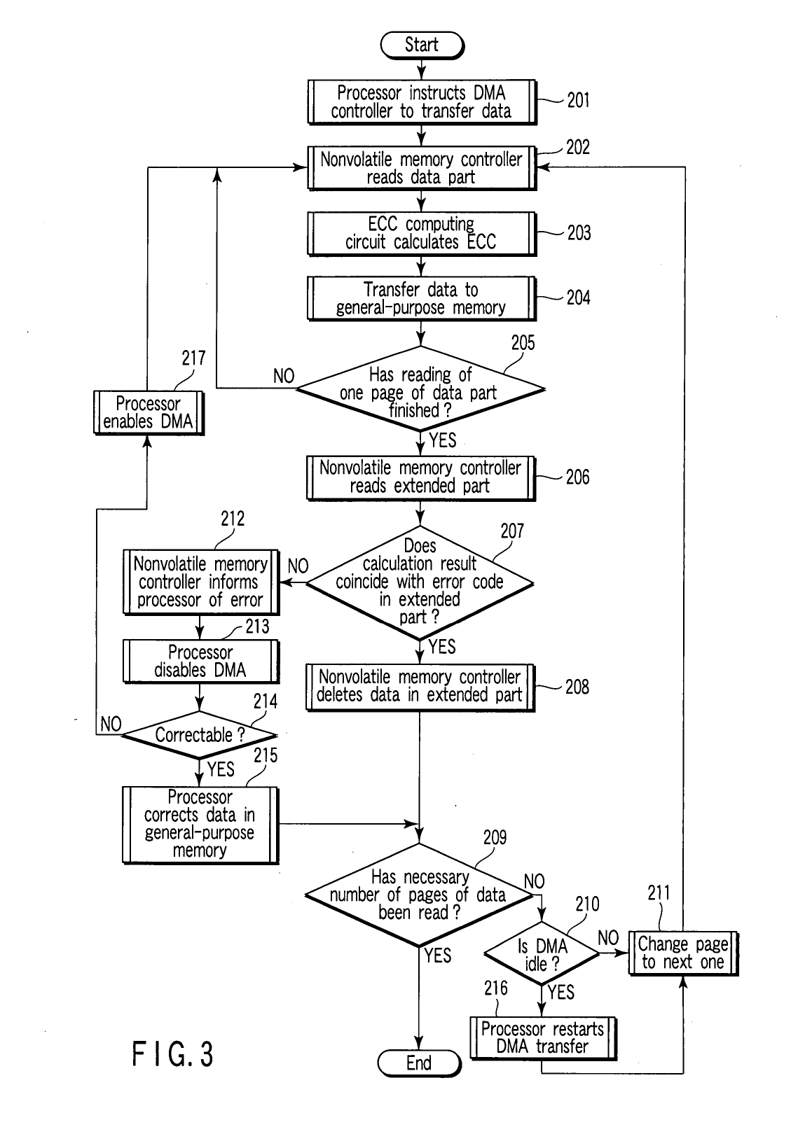

Next, the operation of the memory system of the embodiment will be explained with reference to the configuration of FIGS. 1 and 2 and to the flowchart of FIG. 3.

To copy the data stored in the nonvolatile memory 107 into the general-purpose memory 108, the processor 102 instructs the DMA controller 103 to transfer data from the nonvolatile memory controller 101 to the general-purpose memory controller 106. Specifically, the processor 102 sets the data transfer direction, the transfer start addresses of the nonvolatile memory 107 and general-purpose memory 108, and the data size in the DMA controller 103 (block 201). According to the instruction, the DMA controller 103 instructs the nonvolatile memory controller 101 to read the specified data from the nonvolatile memory 107.

According to the instruction, the nonvolatile memory controller 101 reads data from the nonvolatile memory 107 sequentially (block 202). The nonvolatile memory controller 101 not only stores the read data into the data buffer 104 sequentially, but also transfers the data to the ECC computing circuit 105. In parallel with the storage of data into the data buffer 104, the ECC computing circuit 105 calculates an ECC on the basis of the data stored in the data buffer 104 (block 203). Moreover, the ECC computing circuit 105 stores the result of the calculation into a calculation result storage section 105a. The nonvolatile memory controller 101 outputs (or transfers) the data stored in the data buffer 104 sequentially to the data bus 109. As described above, in the embodiment, the calculation of an ECC is made in parallel with the data transfer in the nonvolatile memory controller 101. The time required for transfer is the same as when an ECC is not calculated.

As the data buffer in which the data read from the nonvolatile memory is stored temporarily, a FIFO memory may be used. In that case, the size of the FIFO memory is determined according to the unit of data transfer in the system. For example, if the data transfer unit of the system is 8 bits, the size of the FIFO memory is 8 bits×2. If the data transfer unit of the system is 16 bits, the size of the FIFO memory is 16 bits×2. By using the FIFO memory in this way, the capacity of the data buffer needed for the nonvolatile memory controller 101 can be reduced.

To return to the explanation of FIG. 3, the DMA controller 103 transfers the output data to the general-purpose memory controller 106. The general-purpose memory controller 106 writes the data into the general-purpose memory 108 (block 204). The nonvolatile memory controller 101 has a counter in it and counts the number of data transfers with the counter, thereby determining whether the transfer of one page of the data part 107a has finished (block 205). The processes in blocks 202 to 205 are repeated until the transfer of one page of the data part 107a has finished.

When the transfer of one page of the data part has finished (Yes in block 205), the nonvolatile memory controller 101 stops the ECC computing circuit 105, starts to read data from the extended part 17c, and stores the read extended part data, that is, the ECC, into the data buffer 104 (block 206). The nonvolatile memory controller 101 compares the extended part (ECC) read into the data buffer with the result of the calculation at the ECC computing circuit 105 stored in the calculation result storage section 105a (block 207).

When the extended part data in the data buffer coincides completely with the calculation result stored in the calculation result storage section 105a (Yes in block 207), the nonvolatile memory controller 101 deletes the extended part data in the data buffer 104 (block 208). When the data on the next page is further read (No in block 209), the nonvolatile memory controller 101 moves (or changes) the data read area of the nonvolatile memory 107 to the next page area and starts to read the data on the next page (blocks 210, 211).

When the extended part data in the data buffer 104 does not coincide with the result calculated at the ECC computing circuit (No in block 207), the nonvolatile memory controller 101 informs the processor 102 of an error interruption (block 212).

Receiving the error interruption, the processor 102 disables the operation of the DMA controller 103 (block 213), reads the extended part data in the data buffer 104 of the nonvolatile memory controller 101, and determines whether an error in the data on the page is correctable (block 214).

If the error is correctable (Yes in block 214), the processor 102 corrects the corresponding data in the general-purpose memory 108 via the general-purpose memory controller 106 (block 215). The processor 102 determines whether the necessary number of pages of data have been read (block 209). If they have not been read, the processor 102 causes (or enables) the DMA controller 103 to operate and restart reading data from the next page (blocks 210, 216, 211).

If the error is uncorrectable (No in block 214), the processor 102 causes the DMA controller 103 to operate again and restart reading data by changing the setting of the DMA controller so as to read the same page again (blocks 217, 202).

As described above, since the calculation of an ECC is made in parallel with (or at the same time with) the data transfer from the nonvolatile memory controller to the general-purpose memory in the embodiment, the operating time can be shortened by the required time for the ECC computing process as compared with a conventional equivalent. That is, the time required for the comprehensive transfer process including the ECC computing process can be shortened. As in the explanation of block 207, since ECC errors are checked for by the nonvolatile memory controller 101, not by the processor 101, that is, only in the nonvolatile memory controller 101, the comprehensive transfer time can be shortened further.

Furthermore, the introduction of DMA transfer into the data transfer from the nonvolatile memory to the general-purpose memory makes it possible to make the transfer process faster. Moreover, if there is no ECC communication error, when the processor 102 sets the DMA controller 102 at the beginning, it need not control the transfer process until the data transfer has been completed and therefore may perform another operation during the data transfer. In addition, even if a communication error has occurred, when the data can be corrected using an ECC, the processor 102 has only to stop the DMA controller 103 temporarily during the correction of the data as in blocks 214, 215, 209, 210, 211 and need not set the DMA controller again.

Although the example where the invention has been applied to data transfer between semiconductor memories has been explained, it is apparent that the invention may be applied to general communication of ECC-added data, such as DVD. Furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory controller comprising:
a reading section which reads data from a data part of a nonvolatile memory including the data part for storing data and an extended part for storing an ECC for the data and provides the read data;
a computing section which calculates an ECC on the basis of the read data in parallel with the reading of data at the reading section and holds a result of the calculation;
a comparing section which reads the ECC stored in the extended part of the nonvolatile memory and compares the read ECC with the result of the calculation at the computing section; and
a section which outputs an ECC error interruption signal when the comparison at the comparing section has shown an disagreement.

2. The memory controller according to claim 1, wherein the reading section includes a FIFO memory for storing the read data temporarily.

3. A memory system comprising:
a nonvolatile memory which includes a data part for storing data and an extended part for storing an ECC for the data;
a memory controller which controls the nonvolatile memory and which includes
a reading section which reads data from the data part of the nonvolatile memory and provides the read data,
a computing section which calculates an ECC on the basis of the read data in parallel with the reading of data at the reading section and holds a result of the calculation,
a comparing section which reads the ECC stored in the extended part of the nonvolatile memory and compares the read ECC with the result of the calculation at the computing section, and
a section which outputs an ECC error interruption signal when the comparison at the comparing section has shown an disagreement;
a general-purpose volatile memory;
a general-purpose memory controller which controls the general-purpose volatile memory;
a DMA controller which controls data transfer between the memory controller and the general-purpose memory controller; and
a processor which controls the DMA controller.

4. The memory system according to claim 3, wherein the reading section includes a FIFO memory for storing the read data temporarily.

5. A data transfer method comprising:
reading data from a data part of a nonvolatile memory including the data part for storing data and an extended part for storing an ECC for the data and providing the read data;
transferring the provided data to a general-purpose volatile memory;
calculating an ECC on the basis of the read data in parallel with the reading of data in the data part and holding a result of the calculation;
reading the ECC stored in the extended part of the nonvolatile memory and comparing the read ECC with the result of the calculation; and
outputting an ECC error interruption signal when the comparison has shown an disagreement.
